(19) United States
(12) Patent Application Publication
(10) Pub. No.: US 2021/0126611 A1
(43) Pub. Date: Apr. 29, 2021

(54) ELECTRIC DEVICE WAFER

(71) Applicant: RF360 EUROPE GMBH, Munchen (DE)

(72) Inventors: Veit MEISTER, Unterhaching (DE); Ulrike RÖSLER, Hebertshausen (DE)

(21) Appl. No.: 16/617,369

(22) PCT Filed: Jun. 6, 2018
(86) PCT No.: PCT/EP2018/064863

§ 371 Date: Nov. 26, 2019

(30) Foreign Application Priority Data
Jun. 8, 2017 (DE) 10 2017 112 647.3

(51) Int. Cl. H03H 9/02; H03H 9/17

(52) U.S. Cl. CPC H03H 9/02574; H03H 9/0222; H03H 9/02976; H03H 9/172; H03H 9/02566

(57) ABSTRACT

A device wafer with functional device structures, comprises a semiconductor substrate (SU) as a carrier wafer, a piezoelectric layer (PL) arranged on the carrier wafer and functional device structures (DS) of a first and a second type realized by a structured metallization on top of the piezoelectric layer (PL). A space charge region is formed near the top surface of the carrier wafer to yield enhanced electrical isolation between functional device structures (DS) of first and second type.

The invention concerns an electric device wafer carrying functional structures of electric devices. Especially, the invention refers to electric devices requiring a piezoelectric layer, preferably electric devices that are using acoustic waves like SAW (surface acoustic waves) for example.

Standard systems of such type are manufactured from device wafers having a piezoelectric layer on a low doped, high resistance Si-wafer. Such wafers can easily be manufactured by e.g. wafer bonding a piezoelectric wafer onto a silicon wafer. Thinning or cleaving of the bonded piezoelectric layer may follow to achieve a desired smaller thickness of the piezoelectric layer.

From the published US patent application, US2015/0102705 A1, another elastic surface wave device is known that uses a specific kind of device wafer for advanced operation of an electric device with elastic waves. A layer system is described that uses a mechanically stable carrier substrate on which a layer system comprising the piezoelectric layer is applied.

Manufacture of the device wafer can be done in a “simple” process and no photolithography is required before the wafer bonding step. But the relatively thin piezoelectric layer and a low conductivity of the Si-Wafer can cause problems with electric isolation and a too high thermal resistance. That is deleterious as a self-heating of the device wafer or of a single device during operation thereof causes a change of properties like resonance frequency due to the TCF (temperature coefficient of frequency) of the device.

Electric isolation between different functional device structures is limited. In the case of SAW devices, the functional structures comprise acoustic tracks. Electric isolation may be required between different acoustic tracks and further a capacitive coupling between different acoustic tracks has to be minimized to avoid worsening of the device performance and cross talk. Further, low doped, high resistance Si-wafers produce higher costs compared to standard substrates on cheap materials.

It is an object of the current invention to provide an electric device wafer that reduces the problems mentioned before. A preferred object is to reduce the thermal resistance of the substrate and to improve the electric isolation between different device structures like acoustic tracks, for example.

These and other objects are solved by a device wafer according to claim 1. Possible variations of the device wafer and preferred embodiments are given by dependent sub-claims.

The invention provides a device wafer with functional device structures. The device wafer comprises a carrier wafer comprising a semiconductor substrate, a piezoelectric layer arranged on the carrier wafer, a structured metallization on top of the piezoelectric layer and functional device structures of a first and a second type realized by the structured metallization. The semiconductor substrate is either entirely doped and thus low-ohmic or comprises at least a doped zone. The semiconductor substrate may comprise silicon or any other semiconductor like GaAs or another III/V compound. Ge is also a possible semiconductor material for the semiconductor substrate.

According to the first embodiment the semiconductor substrate is doped. This enhances the thermal conductivity of the substrate compared to a respective undoped semiconductor material. A material of a higher thermal conductivity enhances dissipating of heat into the bulk material of the semiconductor substrate and prevents the functional devices realized above from being overheated by self-heating.

In the other case the invention improves and extends the properties of the device wafer and the functional devices thereon by drawing on semiconductive properties of the carrier wafer. It is proposed to provide a space charge region near the top surface of the carrier wafer to yield enhanced electrical isolation between functional device structures of a first and a second type. The space charge region is depleted of charge carriers and thus provides a zone of enhanced electrical isolation. Such a space charge region can be yielded in several principle ways. A first way is to form a pn junction by diffusing into the wafer a dopant that provides a kind of conductivity contrary to the conductivity of the remaining carrier wafer. Thereby a doped zone is created.

Along with the first embodiment it is preferred to deposit a high-ohmic epitaxial silicon layer on top of the semiconductor substrate. Then the carrier wafer comprises the highly doped semiconductor substrate and a high-ohmic epitaxial silicon layer.

Besides improved isolation by the low conductivity of the low doped and high-ohmic epitaxial layer this embodiment has the further advantage that the relatively high costs for a high-ohmic semiconductor material as it is used in known devices can be minimized by using only a thin epitaxial layer of the expensive silicon over a less expensive doped semiconductor substrate. In spite of the higher electric conductivity of the semiconductor substrate, the high ohmic epitaxial layer provides sufficient electric isolation.

The high ohmic epitaxial layer may be of the same conductivity type like the highly doped semiconductor substrate. Preferably semiconductor substrate and epitaxial layer are doped with dopants providing respective inverse types of conductivity such that a pn junction forms at the interface between substrate and epitaxial layer. At the pn junction a space charge region forms between the semiconductor substrate and the high ohmic epitaxial silicon layer. The space charge region extends laterally across the whole device wafer parallel and near to the surface thereof and provides further isolation to the bulk material of the substrate.

A doped zone or a doped well may be formed in the epitaxial layer by doping with a dopant providing a respective inverse type of conductivity such that a pn junction forms at the interface between doped zone/doped well and epitaxial layer. At the pn junction another space charge region forms. In the doped zone/well semiconductor elements can be realized.

A further way to provide a space charge region is to apply an electrical field via a BIAS voltage across a doped material that is vertically across the device wafer comprising the carrier wafer. In the electric field charge carrier can enrich at the interface between a conductive and an isolating material that is at the interface between carrier wafer and piezoelectric layer.

The functional device structures are metallic structures that enable proper operation the electric devices formed within the device wafer by using the piezoelectric properties of the piezoelectric layer. The functional device structures may comprise electrodes, conductor lines or metallized areas that may be electrically connected or electrically isolated against each other. Depending on the type of electrical device, the device structures may, for example, comprise interdigital electrodes for a SAW device.

Each of the proposed pn junctions and space charge regions results in an improved electrical isolation. Thereby, electrical isolation between functional device structures of first and second type can be improved. The improvement is achieved by reducing capacitive coupling between the electrically conductive functional device structures and the electrically conductive semiconductor material of the semiconductor substrate wafer.

Further, a highly doped semiconductor substrate wafer provides electromagnetic shielding of the functional device structure from the back side.

The high ohmic epitaxial semiconductor layer can be embodied with a thickness that is relatively low in view of the thickness of the semiconductor substrate wafer. Thus, the relatively high cost of forming an epitaxial layer can be minimized.

According to a further embodiment of the invention, the device wafer comprises first and second surface regions within the carrier wafer. First and second surface regions are facing respective device structures of the first and second type. First and second surface regions are isolated against each other by an isolating barrier. The barrier may extend linearly separating first and second surface region similar like a border. According to another variant the barrier may be formed as a frame surrounding first and/or second surface regions.

The barrier is for electric isolation and may comprise a dielectric material that is per se electrically isolating. Further, the barrier may comprise a zone that is doped inversely with regard to the high-ohmic epitaxial silicon layer the barrier is embedded in. In the first case a trench may be provided and filled at least partly with a dielectric material such that first and second surface regions are isolated against each other by the isolating dielectric. Such a dielectric may be chosen from dielectric inorganic materials as used in current semiconductor technology like silicon oxide for example. But organic materials like resists or lacquer are possible too. It may also be possible to leave the formed trench open (e.g. air isolation).

Such an isolating barrier works in addition to the space charge region that forms between the epitaxial layer and the semiconductor wafer.

When the barrier comprises an inversely doped zone an additional pn junction forms respectively on both sides of the doped zone along at the interface between doped zone and adjacent high-ohmic epitaxial layer. Hence, two pn junctions and two space charge regions adjacent to the doped zone are isolating first and second surface region.

If there are only two different surface regions to be isolated against each other, a linearly extending barrier between the two surface regions or a frame-like barrier surrounding one of the two surface regions would be sufficient. But for further improving the electric isolation each of those surface regions to be isolated against each other may be surrounded by a separate frame.

A barrier formed as a surrounding frame and made by an inversely doped zone can be provided in a high ohmic semiconductor material that may be identical with the substrate wafer. But it is preferred to provide the doped zone within the high ohmic epitaxial silicon layer. In the ladder case, the doped zone forming the barrier extends from the top surface of the high ohmic epitaxial silicon layer through that layer at least to the top surface of the semiconductor substrate.

In a further embodiment a pn junction is formed by providing a doped well in the first and/or second surface region of the semiconductor substrate. The doped well comprises a dopant providing a respective conductivity inverse to the dopant that is present in the semiconductor substrate wafer. A respective surface region comprising the doped well is facing functional device structures on top of the piezoelectric layer. These device structures may be of of a first or a second type. By the pn junction at the outer border of the doped well the functional device structures are isolated against all other functional device structures that are not facing said surface region within the doped well. Other functional device structures of the respective other first or second type may be facing another surface region embedded in another doped well, thereby further improving the electrical isolation. In this connection, improving of electrical isolation means reducing capacitive coupling of functional device structures by means of an electrical conductive structure facing both functional device structures. The electrically conductive structure forms a coupling capacitance to both of the functional device structures. By the invention these couplings are substantially reduced. The effects of the different embodiments may be combined and add up thereby further improving the isolation.

A doped well may be arranged in the first and the second surface region of the high ohmic epitaxial silicon layer. Both surface regions are isolated by respective pn junction that form at the interface between the well and the high ohmic epitaxial silicon layer.

In a preferred embodiment the functional device structures realize a surface acoustic wave device. Hence, device structures of the first and second type respectively comprise at least one acoustic track of a SAW device. Improved electric isolation of two acoustic tracks is achieved by the invention. This prevents crosstalk between different acoustic tracks, improves the operation of the SAW device, and results in an improved signal quality, reduced disturbing signals and if the SAW device is a filter in reduced pass band ripple.

The SAW device may comprise several acoustic tracks that need not be isolated against each other. In this case, a common surface region comprising a single well that is large enough to face all acoustic tracks of the same type would be sufficient.

It may be a further object to avoid a capacitive coupling between device structures within the same acoustic track. In this case, a surface region in the carrier wafer needs to face only part of the acoustic track that is opposing the respective surface region. The other part of the acoustic track facing another surface region can be isolated against the first mentioned surface region by said pn junction or by an additional barrier that may be a doped zone or a trench filled with dielectric or air.

This kind of isolation may be of interest to improve suppression of DMS filters or other longitudinal coupled setups (e.g. multiport resonators MPR or delay lines). Such an isolating part may also influence generation of bulk wave or other harmonics of a SAW structure due to the modulation of the electric field below the piezo layer.

According to a combined embodiment a surrounding frame surrounds a doped well that comprises one of a first or a second surface region. The frame may be located along the lateral border of the doped well such that the frame encloses a region of unitary doping. But it is also possible that the frame is distant from the doped well such that the pn junction at the interface between the doped well and the surrounding semiconductor material is within the area that is surrounded by the frame.

When applying a voltage vertically across a semiconductor layer the voltage produces an electrical field in which electrical charges can migrate according to the sign of the charge, thereby forming a space charge region. This may lead to a depletion region, an enhancement of carriers or an inversion zone. Flowing of an electrical current is prevented by interposing an isolating layer between the two contacts the voltage is applied to. In the case of the present invention and according to a further embodiment a BIAS voltage is applied between the functional device structures and the bulk material of the semiconductor wafer. The piezoelectric layer functions as an electric isolator such that charge carriers enrich in a surface region of the semiconductor substrate wafer adjacent to the isolating piezoelectric layer and next or opposite to the functional device structures and hence next to the top surface of the carrier wafer. Below the enriched zone and deeper within the carrier wafer a depletion zone, and hence a space charge region, forms.

A further effect of this embodiment is that by the charge carriers within the enriched zone a capacitance to the functional devices forms with the piezoelectric layer and any other isolating layer there between as a dielectric. The value of the capacitance is dependent on the value of the applied BIAS voltage. Such a capacitance can influence the properties of the functional devices, respectively the properties of the electric device realized by the functional device structures.

If the functional device structures are part of a SAW device the capacitance induced by the BIAS voltage can add to the static capacitance of a SAW electrode or a SAW resonator, for example. As a consequence thereof, the properties of the SAW device that depend on the static capacitance can change, i.e. the resonance frequency or the pass band frequency of the SAW device for example. By setting a specified BIAS voltage according to this embodiment a tuning of the resonance frequency of the SAW device is possible. But even if no use is made of the additional capacitance, the space charge region induced by the applied BIAS voltage yields an improved isolation of a surface region opposite and facing the functional device structures the BIAS voltage is applied to.

The tuning of a SAW device realized by the functional device structures of the wafer device can be applied to different device structures in a different way. By applying different BIAS voltages to different functional device structures, independent and separate tuning of different SAW devices can be achieved.

By singulating from the device wafer, single electrical devices can be achieved. Singulating can be done by sawing into the device wafer. But any other method of cleaving the device wafer along separation lines is possible too. The device wafer may comprise different electrical devices such that different types of single electric device are achieved. Preferably, the device wafer comprises only one type of electrical devices. Further, a singulated device separated from the device wafer may also comprise different functions realized by separate or connected functional device structures. Those different functions may be connected and can thus interact by a semiconductor element realized in the carrier wafer.

In the above part of the description only those features have been described that are necessary for achieving the effects that are necessary to meet the desired objects. Other features that are known per se for electrical devices known in the art may be applied with a device wafer or an electric device according to the invention too. For example a bonding layer may be necessary to bond a piezoelectric wafer on top of the carrier wafer or to improve the adhesion of the bonded wafers. Such a bonding layer may comprise silicon oxide e.g. or aluminium nitride as well. This bonding layer allows to make an easier and better bonding of the piezoelectric wafer onto the carrier wafer. Other bonding layers are possible too.

Before or during applying the bonding layer measures for reducing surface charges of the silicon substrate can be made. These measures can comprise a physical treatment of the silicon substrate that is used as a carrier, or applying an additional layer for discharging the surface of the silicon substrate. Such measures are known from the art and need not be explained in more detail.

Besides the bonding layer other or additional layers may be inserted into the layer structure of the device wafer between piezoelectric layer and carrier substrate. For example, a TCF (temperature coefficient of frequency) compensating layer may be introduced. Such a TCF compensating layer may comprise silicon oxide. Due to the low thickness of the piezoelectric layer after thinning of the piezoelectric layer the TCF compensating layer can have a low thickness too. Compared to a TCF compensating layer of a SAW device using a thick piezoelectric layer such as a piezoelectric chip the thickness of the TCF compensating layer may be reduced to achieve the same amount of TCF compensation.

As a further layer a mode-forming or a mode-guiding layer may be inserted. As known from the art, such mode-forming layers are introduced to prefer a desired mode or to prevent an undesired mode from being excited. Such a mode -forming layer may comprise a material of high acoustic velocity. A preferred material may comprise polycrystalline silicon or aluminium nitride.

Any kind of passivation is possible as a top layer of the device wafer. This passivation may be applied onto the top surface of the piezoelectric layer covering the metallization of the functional device structures. Another kind of passivation may be applied to the top surface of the piezoelectric layer under the metallic functional device structures. A passivation layer may comprise a silicon oxide layer and/or a silicon nitride layer.

In addition to the passivation layer SAW devices or functional device structures of different types may be encapsulated under a sealing cap that encloses the functional device structure within a cavity between the cap and piezoelectric layer. The cap may be produced by thin-film methods where a cavity is formed by applying a sacrificial layer. In a structuring process part of the sacrificial layer is removed that is structured. Only on those surface portions where a cavity has to be formed material of the sacrificial layer remains. After covering the sacrificial structures with a capping layer, the sacrificial structures may be removed by etching or dissolving.

In the following the invention will be explained in more detail with reference to preferred embodiments and accompanying figures. The figures are drawn schematically only and not to scale. Hence, some details of the inventive devices may be depicted enlarged for better understanding. As a consequence, no ratios of any dimension can be taken from the figures.

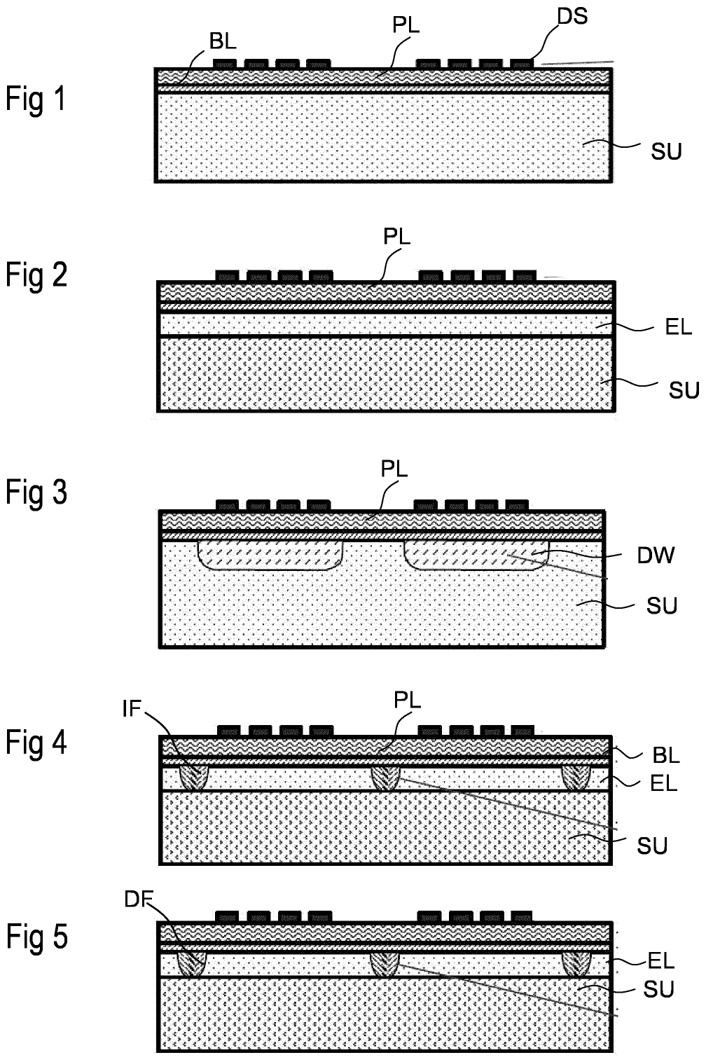

FIG. 1 shows a cross-sectional view through part of a device wafer according to the art;

FIG. 2 shows a device wafer with an epitaxial layer according to an embodiment of the invention;

FIG. 3 shows a device wafer with doped wells according to another embodiment;

FIG. 4 shows according to another embodiment a device wafer comprising an epitaxial layer with an isolating barrier arranged in this layer;

FIG. 5 shows another embodiment of a device wafer with an epitaxial layer comprising a doped zone;

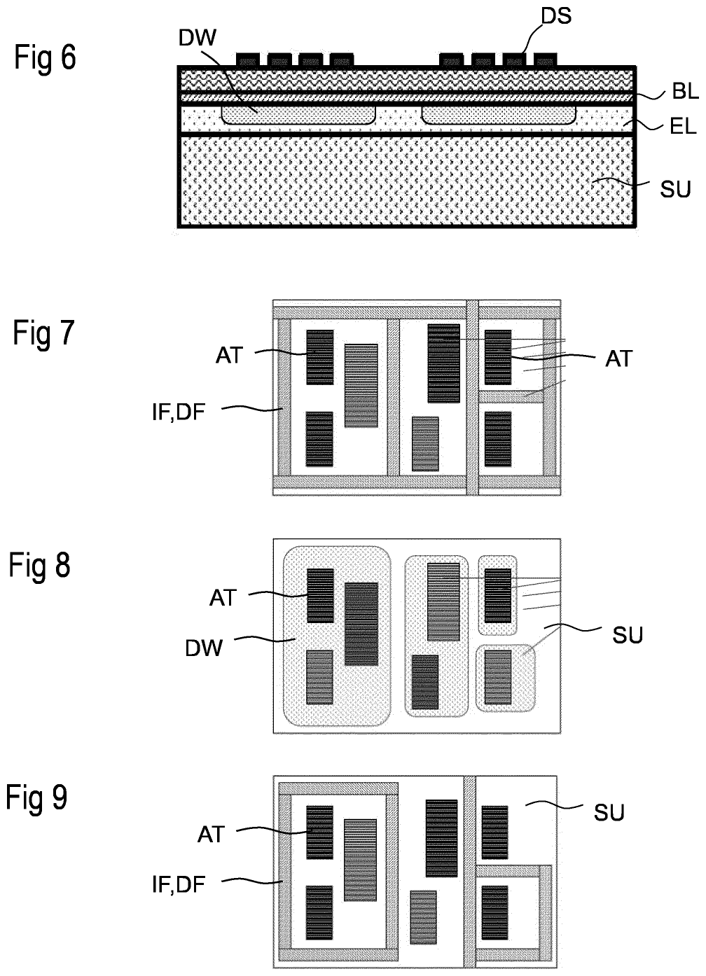

FIG. 6 shows a device wafer with an epitaxial layer including doped wells therein according to another embodiment;

FIG. 7 shows, in a top view, device structures of a device wafer that are enclosed by a barrier formed by an isolating material or doped frame-like zone;

FIG. 8 shows, in a top view, the arrangement of device structures within doped wells;

FIG. 9 shows, in a top view, a relative arrangement of a frame and device structures;

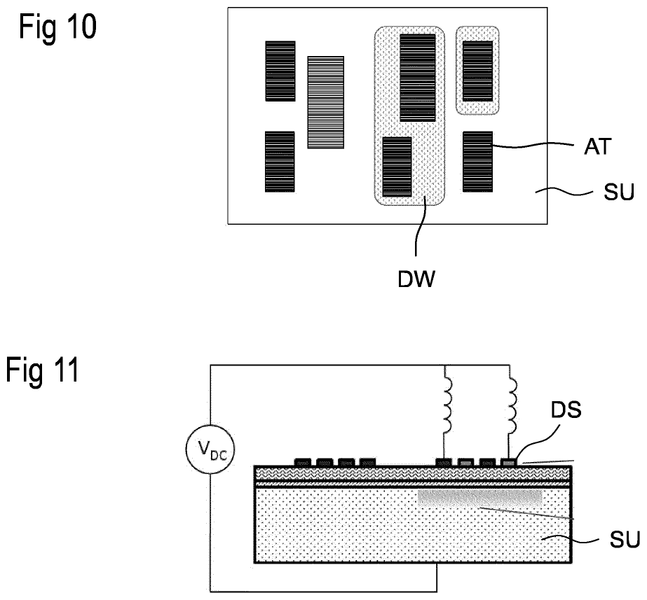

FIG. 10 shows, in a top view, a device wafer where only part of the device structures are arranged within a doped well; and

FIG. 11 shows a cross-sectional view through a device wafer comprising means for applying a BIAS voltage between the device structures and the bulk material of the substrate.

FIG. 1 shows, in a schematic cross-section, a device wafer according to the art. The device wafer comprises a carrier wafer comprising a silicon substrate SU on top of which a layer system is arranged. Such a layer system may comprise a bonding layer BL and a piezoelectric layer PL. The bonding layer may be produced directly on the silicon substrate SU and usually comprises aluminium nitride and/or silicon oxide. A piezoelectric layer PL is wafer-bonded on top of the bonding layer BL. The piezoelectric layer PL may be a thick wafer that is wafer-bonded to the substrate and then reduced in thickness by a grinding process or by a wafer cleavage followed by a polishing process. On top of the piezoelectric layer PL metallic device structures DS may be applied. As shown in FIG. 1, the device structures may comprise interdigital transducer electrodes of a SAW device like a SAW filter, for example.

A disadvantage of the shown device wafer is insufficient electric isolation between different device structures DS.

The device structures DS to be isolated against each other are interfering with each other by capacitive coupling via charge carriers within the substrate SU. To minimize such coupling, a very low doped silicon substrate SU is necessary. As the low doped silicon material is a very clean material having a very low amount of impurities, this material is expensive.

FIG. 2 shows, in a cross-sectional view, a device wafer according to an embodiment of the invention. In contrast to the known device wafer according to FIG. 1, the device wafer comprises a silicon substrate SU that is weakly doped and provides a certain amount of conductivity. On top of the silicon substrate SU a high-ohmic epitaxial layer EL is applied. Any epitaxial silicon deposition may be used to manufacture this epitaxial layer.

To provide a space charge region between epitaxial layer EL and silicon substrate SU, different doping is used for both layers. For example, the silicon substrate SU may have a n⁺ doping. The epitaxial layer may then be low conductive and, for example p⁻ doped. But it is not mandatory to have different type of doping for bulk wafer and epitaxial layer.

The piezoelectric layer PL may be a lithium tantalate layer, for example. But any other piezoelectric material is useful for the invention. The piezoelectric layer may have relatively low thickness of about two times the acoustic wavelength the device is working with. Thicker piezoelectric layers are possible too. However a thicker layer could possibly worsen or complicate a desired interaction of a semiconductor element in the carrier wafer and functional device structures. The epitaxial layer thickness may be in the same order. But a higher or lower thickness may be possible too. In the course of the pn junction between epitaxial layer EL and silicon substrate SU a space charge region forms that isolates the two layers against each other by forming a respective barrier.

FIG. 3 shows a schematic cross-section of a further embodiment. In this example a very low doped silicon substrate SU is used, for example, an n⁻ doped silicon. Near the surface and directly under a group of device structures DS a doped well DW is formed by implanting therein a dopant that provides a conductivity of the contrary type. In the example the doped wells comprise a p⁻ doping. With these doped wells a pn junction is formed at the interface of the doped well and the silicon substrate. A space charge region forms and provides a barrier that prevents charge carriers to leave the doped well. Hence, the doped well provides a perfect isolation of the region opposite to the device structures such that device structures that have to be isolated against each other are arranged opposite to separate and different doped wells DW.

FIG. 4 shows in a cross-sectional view the method to further improve the isolation between different device structures DS. The improvement can be applied to a device wafer according to FIG. 2. In addition to the pn junction between epitaxial layer EL and silicon substrate SU an isolating frame IF is formed as a barrier within the epitaxial layer EL. The isolating frame IF extends from the top surface of the epitaxial layer EL to the top surface of the silicon substrate SU. It may be manufactured by forming a trench, for example by etching, and then filling up the trench with an isolating material like silicon oxide for example. Any other dielectric may be possible too, the filling of the trenches may be accomplished by applying an isolating dielectric to the entire surface of the epitaxial layer before forming the bonding layer BL. The isolating layer is applied in a thickness that is sufficient to totally fill the trenches. Then the surface may be planarized by grinding or back-etching such that a plane surface remains. Alternatively the trench can remain unfilled to provide an air-filled isolating trench. In this case, it may be advantageous to form the trench during manufacturing of the carrier wafer as a last step before bonding the piezoelectric wafer to the carrier wafer.

The isolating frame IF surrounds a region opposite to a type of device structures DS that has to be isolated against other device structures. At the area enclosed by the isolating frame IF the surface of the epitaxial layer EL may be exposed. But it is possible too that the isolating material filling the trench is used at the same time to form a bonding layer.

Alternatively, a bonding layer BL is applied separately on top of the carrier wafer in a usually known manner. Then the piezo layer PL is applied on top of the bonding layer BL and device structures DS are formed on top of the piezoelectric layer. In this embodiment the region of the epitaxial layer EL opposite to a type of device structure DL is isolated against the silicon substrate SU by the pn junction. Two adjacent types of device structures DS are isolated against each other by the isolating frame IF.

FIG. 5 shows another example where a barrier is formed within the epitaxial layer EL as shown in FIG. 2. But in this embodiment the barrier comprises a frame-like doped zone DF. Alternatively, the barrier may extend linearly between two surface regions of the substrate to be isolated against each other.

The used doping is contrary to the doping of the remaining epitaxial layer EL such that a pn junction is formed between the low doped epitaxial layer EL and the doped frame-like zone DF. In this example, the doped zone may be n+ doped. The doping may comprise applying a doping mask to the epitaxial layer EL before diffusing in or implanting the dopant and before applying the bonding layer BL. In the doping mask only those regions are exposed where the doped zone DF is to be produced.

In an embodiment according to FIG. 6 an isolation inverse to the embodiment shown in FIG. 5 used. While the embodiment of FIG. 5 uses doped zones as a barrier between surface regions, doped wells are formed in a surface region within the epitaxial layer EL. This is similar to the embodiment of FIG. 3 with the advantage that the weakly doped and low conductive epitaxial layer EL has only a small thickness over a silicon substrate SU that may be strongly doped. Besides the pn junction between epitaxial layer EL and silicon substrate SU, a further pn junction is formed between the doped wells and the remaining area of the epitaxial layer besides the doped wells. While in the embodiment of FIG. 5 a frame-like zone DF is doped and the epitaxial layer remains undoped, FIG. 6 provides an embodiment where the region opposite to the device structures is conductive and the remaining epitaxial layer is low conductive.

FIG. 7 shows in a top view onto a device wafer how different device structures can be isolated against each other. As a device structure DS, acoustic tracks AT of a SAW device are formed. By a barrier like isolating frames IF or doped zones DF different areas of the carrier wafer may be isolated against each other. Each isolated area may comprise one or more device structures as shown in the embodiment. While the area shown on the left side of the figure comprises three acoustic tracks AT surrounded by an isolating frame IF or a doped zone DF, the area shown in the middle of the figure comprises two acoustic tracks AT within one enclosing barrier and in the area shown on the right side of the figure only one acoustic track each is surrounded by a respective isolating frame IF or frame-like doped zone DF.

The frames are formed and arranged between device structures DS that have to be isolated against each other. These may be for example between interdigital transducer electrodes of an input transducer and an output transducer. It is also possible to use this kind of isolation to separate parts within a track from each other, e.g. in DMS structures (IN vs. OUT), to isolate parts of MPR filters (multi-port resonator) or to separate parts of cascaded resonators (e.g. frame/trench below “bus-bar” between tracks of a cascade).

FIG. 8 is a top view onto a device wafer according to the embodiment shown in FIG. 3 or FIG. 6. The figure shows how the doped wells may be arranged within the surface of the silicon substrate or the epitaxial layer. Similar to the embodiment of FIG. 7, several device structures like acoustic tracks AT may be arranged within one doped well DW. Different doped wells DW may comprise a different number of device structures as shown. Accordingly, the doped wells may comprise different surface areas.

FIG. 9 shows another arrangement of isolating frames IF or doped frame-like zones DF in a top view on a device wafer according to the invention. On the left side, a frame surrounds and isolates a number of device structures like acoustic tracks AT. Two other acoustic tracks shown in the middle of the figure do not need a surrounding frame, but are isolated against the acoustic tracks on the right part of the figure by a non-surrounding barrier zone that is formed linearly to isolate the not-surrounded device structures against the surrounded and non-surrounded device structures on the right side. As shown in FIG. 9, barriers formed as surrounding frames and linearly extending isolating zones may be present on the same device wafer. But it is also possible that only linearly extending isolating zones are necessary to isolate different regions on top of the silicon substrate, each region being opposite to one or more device structures that need to be isolated against other device structures.

FIG. 10 shows another possibility to arrange doped wells in a silicon substrate or an epitaxial layer according to the embodiments shown in FIGS. 3 and 6. In FIG. 10 two doped wells DW comprise at least one device structure that is at least one acoustic track AT. Other acoustic tracks are arranged outside the doped wells DW. In spite of not being arranged in the doped well, the device structures or acoustic tracks shown in the left part of FIG. 10 are isolated against the device structures arranged in a doped well by virtue of the pn junction between the doped well and the remaining undoped area outside the doped well DW.

FIG. 11 shows a cross-section of a device wafer according to another embodiment. A space charge region is formed as a depletion region due to an applied DC BIAS voltage V_{DC}. The BIAS voltage is applied between device structures DS and the bulk material of the silicon substrate SU, for example by applying a metallized area on the bottom surface of the silicon substrate SU. Because of the BIAS voltage, charge carriers enrich in a zone opposite to the device structures the BIAS voltage is applied to. As a result enhanced conductivity in the region opposite to the device structures is achieved and a capacitance forms between the device structures and the enriched region opposite thereof in the upper surface of the silicon substrate. This capacitance may add to the capacitance of the device that the device structures belong to. By varying the capacitance of the device, properties thereof may be changed. As a consequence of an enhanced static capacitance of an interdigital transducer electrode, the resonance frequency thereof may be tuned. But every other property that is dependent on a capacity may be tuned by such a DC BIAS voltage too.

Applying of an inverse bias voltage may also lead to a depleted zone below the structure reducing the capacitance in this region and thus, resulting in the same effect of tuning resonance frequency.

The invention has been explained and depicted with reference to a limited number of embodiments and figures. However the scope of the invention is not restricted to the embodiments. As in most figures only one a single aspect of the invention is shown, it is within the scope of the invention to combine different features shown in different figures. Hence, it is possible to combine a doped well and an isolating or a doped frame. Further, each lateral structuring may be done within an epitaxial layer or within the silicon substrate alternatively or additionally. But in most cases photolithography, epitaxial deposition or doping processes or combinations of them needed before wafer bonding. Other manufacturing steps of structuring and/or doping the carrier wafer may alternatively be done after wafer bonding. E.g. ion implanting can be done through any barrier layer or other layer to form a structures at a depth within the wafer that is depended on the implanting energy e.g. the ion accelerating field. Another step may use the transparency of the piezoelectric layer for a range of wavelengths such that a laser can be used to specifically form a structure that is buried under a covering layer. These buried structures can comprise isolating trenches or any other discontinuity within the carrier wafer.

1. A device wafer with functional device structures, comprising
a carrier wafer comprising a semiconductor substrate (SU)
a piezoelectric layer (PL) arranged on the carrier wafer
a structured metallization on top of the piezoelectric layer; and
functional device structures (DS) of a first and a second type realized by the structured metallization;
wherein
either the semiconductor substrate (SU) is entirely doped and thus low-ohmic or the carrier wafer comprises at least a doped zone.

2. The device wafer of claim 1, wherein the carrier wafer comprises
a highly doped semiconductor substrate (SU) and
a high-ohmic epitaxial silicon layer deposited on top of the semiconductor substrate.

3. The wafer of claim 1,
wherein the semiconductor substrate (SU) is entirely doped to enhance electrical and thermal conductivity of the substrate in view of a respective undoped material
wherein a weakly doped and thus high ohmic epitaxial silicon layer (EL) of inverse conductivity is arranged across the entire surface of the carrier wafer between the semiconductor substrate and the piezoelectric layer
wherein a space charge region is formed between semiconductor substrate and the high ohmic epitaxial silicon layer.

4. The wafer of claim 3, comprising a first and a second surface region within the carrier wafer, wherein
first and second surface region are facing respective device structures (DS) of the first and second type
first and second surface regions are isolated against each other by a barrier formed as surrounding frame or as a linearly extending zone
the barrier extends from the top surface of the high ohmic epitaxial silicon layer through the layer at least to the top surface of the semiconductor substrate
wherein the barrier comprises a dielectric material or a doped zone that is doped inversely with regard to the high ohmic epitaxial silicon layer (EL) the barrier is embedded in.

5. The wafer of claim 1, wherein the semiconductor substrate (SU) comprises a doped well (DW) in the first and/or a second surface region thereof, the doped well facing respective device structures (DS)
wherein a first and a second surface region are isolated against each other by a pn junction that forms at the interface between the well and the surrounding semiconductor substrate.

6. The wafer of claim 1, wherein a doped well (DW) is arranged in the first and a second surface region of the high ohmic epitaxial silicon layer (EL)
wherein first and second surface regions are isolated against each other by a pn junction that forms at the interface between the doped well (DW) and the high ohmic epitaxial silicon layer (EL).

7. The wafer of claim 1, wherein the barrier surrounds a doped well that comprises one of first or second surface regions.

8. The wafer of claim 1, wherein the functional device structures (DS) of first and second type comprise at least one acoustic track (AT) of a SAW device each.

9. The wafer of claim 1, wherein the device wafer is adapted to apply a BIAS voltage between functional device structures (DS) and the bulk material of the semiconductor wafer (SU) such that a zone at the top surface of the semiconductor wafer is enriched with charge carriers and forms together with the functional device a capacitive element with the intermediate piezoelectric layer as a dielectric.

10. The wafer of claim 9, wherein a first BIAS voltage is applied to first functional device structures and a second BIAS voltage is applied to second functional device structures
wherein first and second BIAS voltage are different such that capacitive elements of different capacitance are formed.

11. An electric device, comprising:
a carrier wafer comprising a semiconductor substrate (SU)
a piezoelectric layer (PL) arranged on the carrier wafer
a structured metallization on top of the piezoelectric layer; and
functional device structures (DS) of a first and a second type realized by the structured metallization;
wherein
either the semiconductor substrate (SU) is entirely doped and thus low-ohmic or the carrier wafer comprises at least a doped zone.
